(19) United States
(12) Patent Application Publication
(10) Pub. No.: US 2022/0139925 A1
(43) Pub. Date: May 5, 2022

(54) Semiconductor Memory Device And Method Making The Same

(71) Applicant: ChangXin Memory Technologies, Inc., Hefei City (CN)

(72) Inventor: Mao-Hua Su, Hefei City (CN)

(21) Appl. No.: 17/431,035

(22) PCT Filed: May 29, 2020
(86) PCT No.: PCT/CN2020/093420

§ 371 Date: Aug. 13, 2021

(30) Foreign Application Priority Data
Dec. 2, 2019 (CN) 201911213052.6

(51) Int. Cl. H01L 27/108

(52) U.S. Cl. CPC H01L 27/10888

(57) ABSTRACT

This application relates to a semiconductor memory device and a method of forming the same. The method includes the following steps: providing a substrate with a bit line contact area in the substrate, wherein the surface of the substrate is disposed with a dielectric layer; forming a through trench penetrating the dielectric layer and exposing the bit line contact area; filling a first conductive material in the trench to forum a bit line, wherein the top surface of the bit line is configured to be lower than the top surface of the dielectric layer; filling an insulating material in the trench to form a bit line cap layer on the top surface of the bit line. This application does not cause misalignment problem due to the small line width of the bit line and in addition, reduces the internal resistance inside the memory device.

### CROSS REFERENCES TO RELATED APPLICATIONS

This application claims the benefit of priority to CN Patent Application CN 20191121305 filed on Dec. 2, 2019, both entitled “SEMICONDUCTOR MEMORY DEVICE AND METHOD MAKING THE SAME”, the contents of which are incorporated herein by reference in its entirety.

### TECHNICAL FIELD

This application relates to the technical held of semiconductor manufacturing, in particular to a semiconductor memory device and a method of making it.

### BACKGROUND

Dynamic Random Access Memory (DRAM) is a commonly used semiconductor device in electronic equipment such as computers. It is composed of a plurality of memory cells, and each memory cell usually includes a transistor and a capacitor. The gate of the transistor is electrically connected to the word line, the source is electrically connected to the bit line, and the drain is electrically connected to the capacitor. The word line voltage on the word line can control the turning on and off of the transistor, so that data information stored in the capacitor can be read through the bit line, or data information can be written into the capacitor.

As the feature size of semiconductor integrated circuit devices continues to shrink, the requirements for the, manufacturing process of semiconductor devices such as DRAM are getting stricter. Among them, design of the bit-lines in the dense array area has become very important. Currently, SADP (Self-Aligned Double Patterning) transfers pattern images to the final metal layer and/or polysilicon layer, and then a layer of nitride material is grown as an insulation layer through an atomic layer deposition process. In the above process, stripping of the photoresist layer and the implementation of the wet cleaning process will cause side wall etching of the polysilicon at the bottom of the bit lines. In addition, the polysilicon surface is easily oxidized to form a self-oxidation layer. The side wall etching and self-oxidation of the polysilicon will increase resistance on the conductive lines, especially when the bit line process is scaled down to 10 nm, this resistance increase phenomenon has become more obvious.

Therefore, how to avoid problems such as the bit line undercutting and self-oxidation during the formation process, and reduce the internal resistance of the semiconductor memory device, thereby improving the yield of the semiconductor memory device, has become an urgent problem.

### SUMMARY

This application provides a semiconductor memory and a forming method thereof, which are used to solve the problem of large internal resistance of the existing semiconductor memory, so as to improve tile yield of the semiconductor memory.

The method for forming a semiconductor memory device, comprising a plurality of steps: providing a substrate having a bit line contact area and a dielectric layer disposed on a top surface of the substrate; forming a trench penetrating the dielectric layer and exposing the bit line contact area; filling a first conductive material in the trench to form a bit line, wherein a top surface of the bit line is configured to be lower than a top surface of the dielectric layer; and filling in the trench with an insulating material to fours a bit line capping layer on the top surface of the bit fine.

According to another embodiment of the disclosure, a semiconductor memory device comprises: a substrate including a bit line contact area; a dielectric layer disposed on a top surface of the substrate, wherein the dielectric layer comprises a trench penetrating the dielectric layer and exposing the bit line contact area; a diffusion bather layer disposed at least on a sidewall of the trench; a bit line filled in the trench, wherein sidewalls of the bit line are surrounded by the diffusion barrier layer, wherein the bit line is electrically connected to the bit fine contact area, and wherein a top surface of the bit line is configured to be lower than a top surface of the dielectric layer; and a bit line capping layer disposed on the trip surface of the bit line and tilling in the trench.

The method for forming the semiconductor memory device provided in the embodiments includes forming a trench penetrating the dielectric layer to make a bit line profile, and then filling the trench a first conductive material to form a bit line, in comparison with the existing methods of forming a bit line by depositing a conductive film layer followed by subsequent patterning of the conductive film layer into the bit line. First, since the bit line is formed by trench filling, there is no bending defects due to the small line width of each bit line. In addition, since there is no need to perform wet cleaning on the bit line metal or polysilicon, problems such as bit line sidewall erosion and sidewall oxidation are avoided and electron conductivity is improved, thereby reducing the internal resistance of the semiconductor memory device.

It should be understood that the above general description and the following detailed description are only exemplary and cannot limit the present disclosure.

### BRIEF DESCRIPTION OF THE DRAWINGS

By describing its exemplary embodiments in detail with reference to the accompanying drawings the above and other objectives, features and advantages of the present disclosure will become more apparent.

FIG. 1 is a flowchart of a method for forming a semiconductor memory in a specific embodiment of this application.

FIGS. 2A-2N are schematic across sectional views of a semiconductor memory structure in various steps in the process according to some embodiments of this application.

### DETAILED DESCRIPTION OF THE PREFERRED EMBODIMENTS

Implementations of the present disclosure are illustrated below through specific embodiments. Those skilled in the art can easily understand other advantages and efficacy of the present disclosure according to the content disclosed in this specification. The present disclosure can also be implemented or applied through other different specific implementations. Various modifications or variations can also be made on details in this specification based on different opinions and applications without departing from the spirit of the present disclosure.

It should be noted that, the figures provided in this embodiment merely illustrate the basic conception of the present disclosure schematically. Therefore, the figures only show components related to the present disclosure, and are not drawn according to the quantity, shapes and sizes of components during actual implementation. The pattern, quantity and ratio of components during actual implementation can be changed arbitrarily, and the component layout may also be inure complex.

The present disclosure effectively overcomes various disadvantages in the current techniques and hence has high industrial usage value. The foregoing embodiments only illustrate the principle and efficacy of the present disclosure exemplarily, and are not meant to limit variations of the technique. Any person skilled in the art can make modifications on the foregoing embodiments without departing from the spirit and scope of the present disclosure. Accordingly, all equivalent modifications or variations completed by those with ordinary skill in the art without departing from the spirit and technical thinking disclosed by the present disclosure should fall within the scope of claims of the present disclosure.

Example embodiments will now be described more fully with reference to the accompanying drawings. However, the example embodiments can late implemented in various fours, and should not be construed as being limited to the examples set forth herein; on the contrary, the provision of these embodiments makes the present disclosure more comprehensive and complete, and fully conveys the concept of the example embodiments to those skilled in the art. The drawings are only schematic illustrations of the present disclosure and are not necessarily drawn to scale. The same reference numerals in the figures denote the same or similar parts, and thus their repeated description will be omitted.

Furthermore, the described features, structures or characteristics can be combined in one or more embodiments in any suitable manner, hi the following description, many specific details are provided to give a sufficient understanding of the embodiments of the present disclosure. However. those skilled in the art will realize that the technical solutions of the present disclosure can be practiced without one or more of the specific details, or other methods, components, devices, steps, etc. can be used. In other cases, well-known structures, methods, devices, implementations, or operations are not shown or described in detail to avoid overwhelming attention and obscure all aspects of the present disclosure.

In addition, the terms “first” and “second” are only used for descriptive purposes, and cannot be understood as indicating or implying relative importance or implicitly indicating the number of indicated technical features. Thus, the features defined with “first” and “second” may explicitly or implicitly include one or more of these features.

The specific implementations of the semiconductor memory and its forming method provided by this application will be described in detail below with reference to the accompanying drawings.

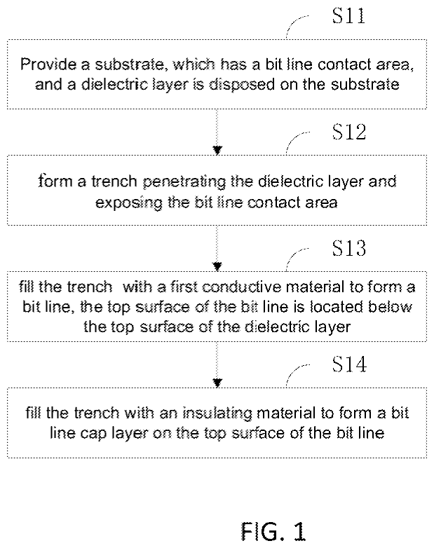

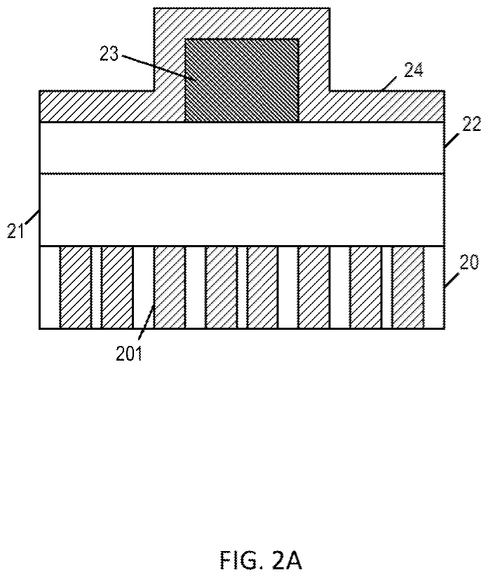

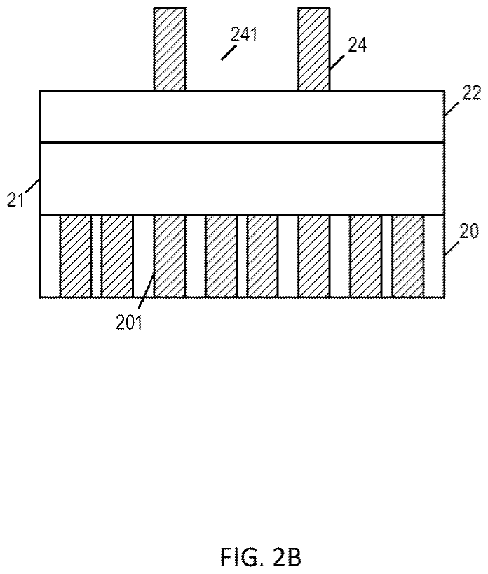

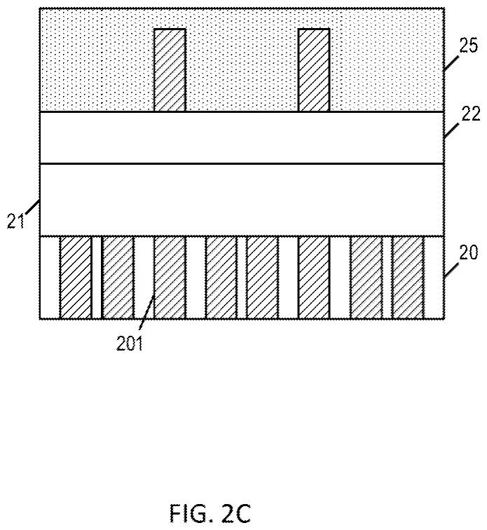

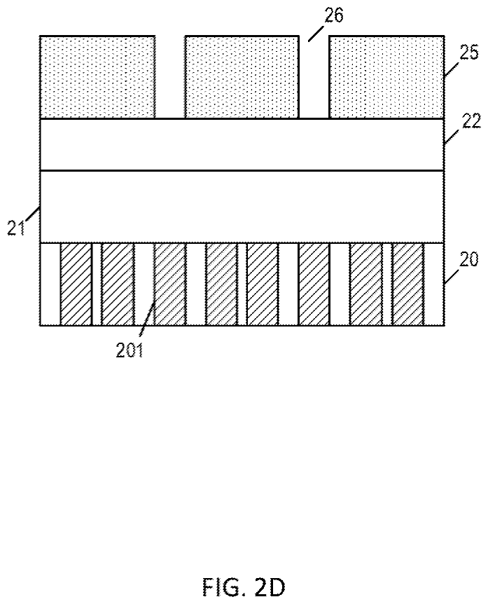

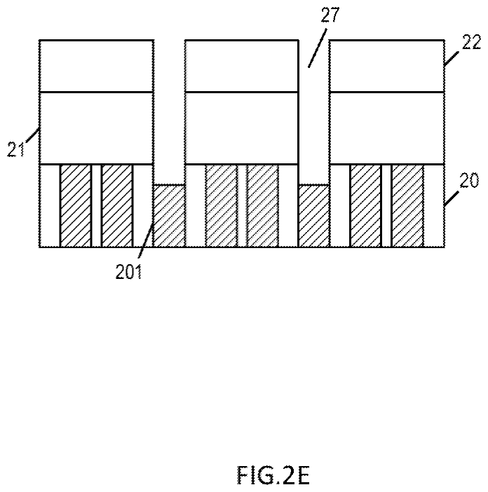

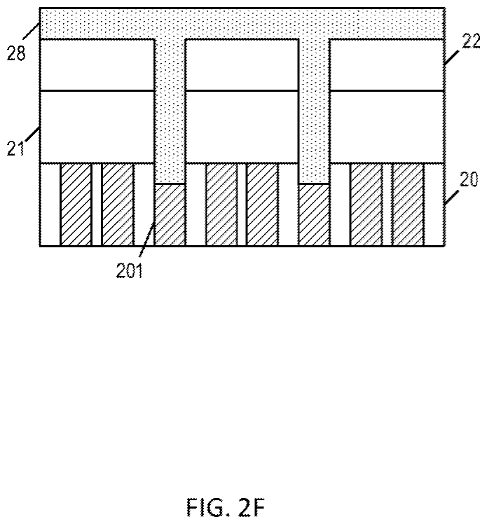

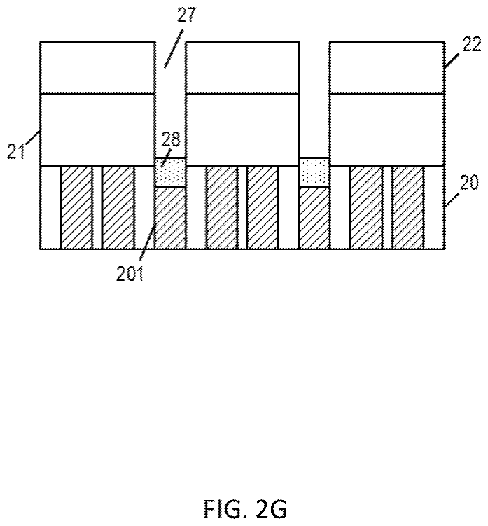

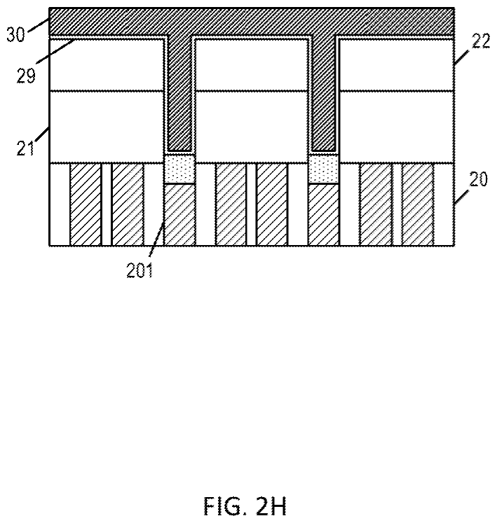

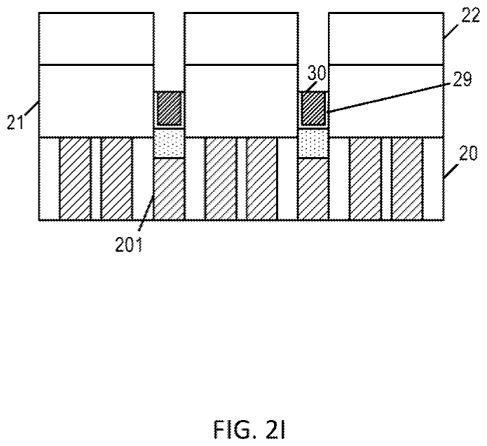

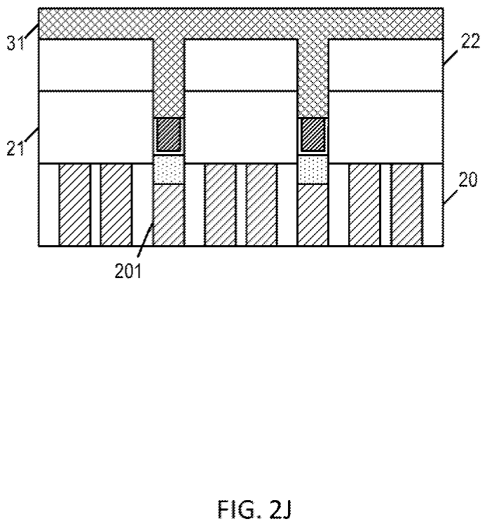

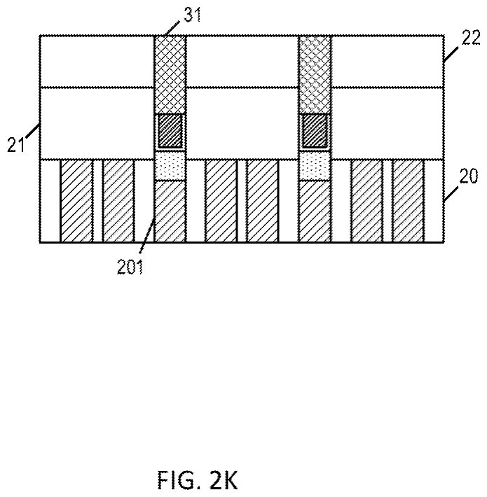

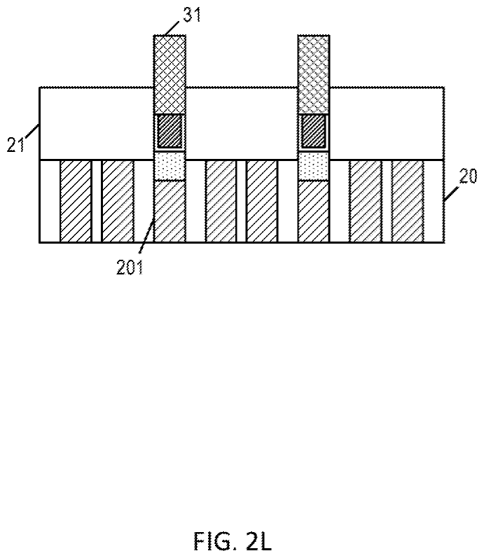

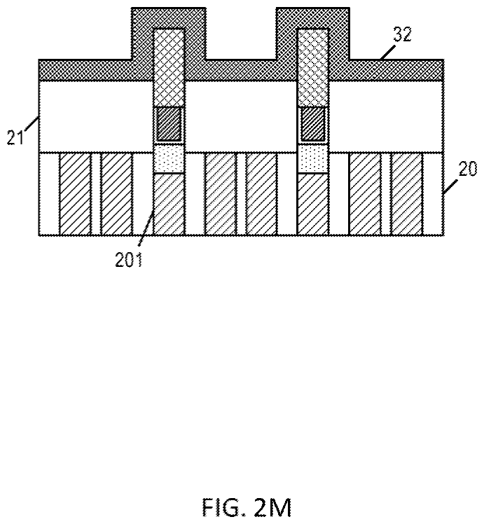

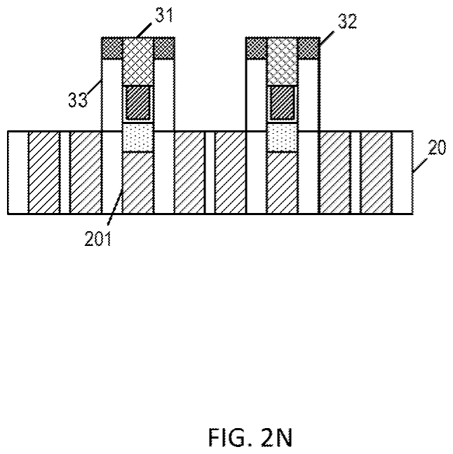

This embodiment provides a method for forming a semiconductor memory device. FIG. 1 is a flowchart of the method for liming the semiconductor memory device according to an embodiment of this application. 2A are schematic cross-sectional views of a semiconductor memory structure in various steps in the process according to some embodiments of this application. The semiconductor memory described in this specific embodiment may be, but is not limited to, a DRAM memory device. As shown in FIGS 1 and 2A-2N, the method for forming the semiconductor memory device according to the embodiment includes the following steps:

In step S11, a substrate 20 is provided which has a bit line contact area 201, and a dielectric layer 21 is disposed on the surface of the substrate 20.

Specifically, the substrate 20 may be a silicon (Si) substrate, a germanium (Ge) substrate, a silicon-germanium (SiGe) substrate, silicon on insulator (SOI), or germanium on insulator (GOI) or the like. In this specific embodiment, the substrate 20 is an Si substrate as an example. The substrate 20 has a plurality of active areas (AA) arranged in an array, and adjacent active areas are electrically isolated by a shallow trench isolation structure (STI). The bit line contact area 201 is located in the active area.

Step S12, forming a trench 27 penetrating the dielectric layer 21 and exposing the bit line contact area 201, as shown in FIG. 2E.

Optionally, the specific steps of forming the trench 27 penetrating the dielectric layer 21 and exposing the bit line contact region 201 include the steps below;

Forming a liner layer 22 on the surface of the dielectric layer 21.

Foaming a first mask layer 24 on the surface of the liner layer 22, the first mask layer 24 has an opening 241 exposing the liner layer 22, as shown in FIG. 28.

Forming a second mask layer 25 tilling the opening 241, as shown in FIG. 2C.

Then the first mask layer 24 is etched back, and an etching window 26 exposing the liner layer 22 is formed in the second mask layer 25 as shown in FIG. 2D.

The dielectric layer 21 is etched aligned with the etching: window 26 to form a trench 27 that penetrates the dielectric layer 21 and the liner layer 22, then the bit line contact area 201 gets exposed, as shown in FIG. 2E.

Optionally, the specific steps of forming the first mask layer 24 on the surface of the liner layer 22 include:

Forming a photoresist layer 23 on the surface of the liner layer 22, the photoresist layer 23 has an initial opening exposing the liner layer 22.

Forming the first mask layer 24 covering the sidewalls of the initial opening, as shown in FIG. 2A.

The photoresist layer 23 is removed, and an opening 241 exposing the liner layer 22 is formed in the first mask layer 24.

Specifically, first, the liner layer 22 is deposited on the surface of the dielectric layer 21 by applying a chemical vapor deposition process, a physical vapor deposition process or other processes. Next, the photoresist layer 23 with initial openings is formed on the surface of the liner layer 22. After that, the first mask layer 24 is deposited on the photoresist layer 23 and the exposed surface of the liner layer 22 to form a structure as shown in FIG. 2A. Then, the first mask layer 24 is etched back to remove the first mask layer 24 on the surface of the liner layer 22 and the top surface of the photoresist layer 23, leaving only the photoresist layer 23 and the first mask layer 24 on the photoresist's sidewalls; afterwards, the photoresist layer 23 is stripped to form a structure as shown in FIG. 2B. Next, the opening 241 is backfilled to form the second mask layer 25 covering the top surface of the first mask layer 24 and the inner wall of the opening 241, as shown in FIG. 2C. Then the second mask layer 25 is etched back to expose the first mask layer 24; after that the first mask layer 24 is removed by a dry etching or wet etching process An etching window 26 exposing the liner layer 22 is formed in the second mask layer 25, as shown in FIG. 2D. Finally, the liner layer 22, the dielectric layer 21 and part of the substrate 20 are etched through along the etching window 26 to form the trench 27, and the second mask layer 25 is peeled off, after that, the structure shown in FIG. 2E is acquired.

In this specific embodiment, by adjusting the thickness of the first mask layer 24 located on the sidewalk of the photoresist layer 23, the width of the trench 27 to be formed subsequently can be controlled.

In this embodiment, the trench 27 extends all the way down to the inside of the substrate 20 to further reduce the contact resistance inside the semiconductor memory device and to provide better isolate adjacent bit lines. In other specific embodiments, one can also extend the trench 27 only to the top surface of the substrate 20 based on actual needs.

There needs a high etch selection ratio between the first mask layer 24 and the second mask layer 25 daring the hole etching so as to facilitate the subsequent selective etching of the first mask layer 24. Optionally, the material of the liner layer 22 is an oxide material, the material of the dielectric layer 21 is silicon nitride, the material of the first mask layer 24 is an amorphous silicon material, and the second mask layer 25 is an organic mask material. For example, the material of the second mask layer 25 may be spin-on-carbon (SOC).

Step S13, the trend with a first conductive material to form a bit line 30, the top surface of the bit line 30 is located below the top surface of the dielectric layer 21, as shown in FIG. 2I.

Optionally, before forming the bit line 30, the method further includes the following steps:

A second conductive material is filled in the trench 27 to form a bit line contact layer 28 on the top surface of the bit line contact region 201, as shown in FIG. 2G.

Optionally, the trench 27 extends into the substrate 20, the bit line contact layer 28 extends above the substrate 20, and the top surface of the bit line contact layer 28 extends into the trench below the top surface of the dielectric layer 21.

Optionally, the specific steps of forming the bit line 30 include:

Forming a diffusion barrier layer 29 On the sidewalk of the trench 27 and the top surfaces of the bit line contact layer 28; and filling the trench 27 with a first conductive material to form a bit line 30 on the surface of the diffusion barrier layer 29, as shown in FIG. 2H.

Optionally, the first conductive material is composed of a metal material, such as tungsten; the second conductive material is composed of a polysilicon material, and the material of the diffusion barrier layer 29 may be composed of titanium nitride.

Specifically, after the trench 27 is formed, first, a poly silicon material is disposed on the top surface of the liner layer 22 and is filling into the trench 27 to form a bit line contact layer 28 as shown in FIG. 2F. Then, the bit line contact layer 28 is etched back, and the top surface of the bit line contact layer 28 is etched down to be lower than the upper surface of the dielectric layer 21, as shown in FIG. 2G. Then, the diffusion barrier layer 29 is formed on the sidewalls of the trench 27, the top surface of the bit line contact layer 28 and the top surface of the liner layer 22, and a metal material is filled in the trench 27 after to form the bit line 30 on the surface or the diffusion barrier layer 29, that is, the bottom suite c and sidewalls of the bit line 30 are protected by the diffusion barrier layer 29, as shown in FIG. 2H. Wherein, the diffusion barrier layer 29 disposed on the sidewalls of the bit line 30 can effectively prevent the metal in the bit line 30 from diffusing into the dielectric layer 21 and liner layer 22; the diffusion barrier layer 29 at the bottom surface of the bit line 30 serves as the work function layer interfacing the bit line 30 (metal material) and the bit line contact layer 28 (poly silicon material) and plays a transitional role. After that, the bit line 30 and the diffusion barrier layer 29 are etched back, and the top surfaces of the bit line 30 and the diffusion barrier layer 29 are etched to be lower than the upper surface of the dielectric layer 21, that is, the depth of the bit line 30 and the diffusion barrier layer 29 is such that the top surface of the bit line 30 is flush with the top surface of the diffusion barrier layer 29, and forms a structure as shown in FIG. 2I. By fuming the bit line contact layer 28, the contact resistance between the bit line contact area 201 and the bit line 30 can be reduced.

In this specific embodiment, since the bit line contact layer 28 and the bit lino 30 are both formed by a trench filling process, first, the good alignment between the bit line contact layer 28 and the bit line 30 is ensured, in addition, the geometry avoids the defects that the feature size of either the bit line contact layer 28 or the bit line 30 is too small so easy to bend, and no photoresist wet development and ashing/cleaning process of the bit line contact layer are required, so this method avoids problems such as undercutting and natural oxidation or the sidewalk of the bit line contact layer 28, thereby reducing the internal resistance or the semiconductor memory device and improving its performance.

In step S14, an insulating material is fined in the trench 27 to form a bit line cap layer 31 on the top surface of the bit line 30, as shown in FIG. 2K

Specifically, after etch back the top surface of the bit line 30 and the diffusion barrier layer 29 to below the top surface of the dielectric layer 21, an insulating material is disposed to fill the trench 27 and on the top surface of liner layer 22, to form a bit line cap layer 31 as shown in FIG. 2J is formed. Then, the bit line cap layer 31 is etched back or polished by a chemical mechanical planarization process to remove the bit line cap layer 31 above the top surface of the liner layer 22 to expose the liner layer 22, such as shown in FIG. 2K. Next, a wet etching process is applied to remove the liner layer 22 and form the structure shown in FIG. 2L.

Optionally, the bit line capping layer 31 extends out of the dielectric layer 21; after forming the bit line capping layer 31 on the top surface of the bit line 30, the method further includes the following steps:

Forming, an isolation layer 32 on the sidewalls of the bit line cap layer 31.

The dielectric layer 21 is etched wing the isolation layer 32 as a mask pattern to expose the substrate 20, and the dielectric layer 21 remaining on the surface of the bit line 30 serves as a sidewall protection layer 33, as shown in FIG. 2N.

Specifically, after the liner layer 22 is removed, the exposed bit line cap layer 31 extends beyond the upper surface of the dielectric layer 21 At this point, an atomic layer deposition process is applied to deposit the isolation layer 32 and the exposed surfaces of the bit line caps. The surface of the dielectric layer 21 and the exposed bit line cap layer 31 are as shown in FIG. 2M. Then the isolation layer 32 is etched back to remove the isolation layer 32 on the top surfaces of the bit line cap layer 31 and the exposed surface of the dielectric layer 21 leaving only the isolation layer 32 on the sidewalk of the bit line cap layer 31. Afterwards, the dielectric layer 21 is etched using the isolation layer 32 covering the sidewalls of the bit line cap layer 31 as a mask pattern, leaving only the sidewalls on the bit line 30 and part of the bit line cap 31. The dielectric layer 21 on the sidewalk of the layer 31 forms the sidewall protection layer 33, that is, separate dielectric layer 33 will protect different sidewalk for each of the bit lines 30 in an one-to-one correspondence. In the process of etching the dielectric layer 21, part of the isolation layer 32 and part of the bit line capping layer 31 are also etched away simultaneously, so that the total depth or the isolation layer 32 and the bit line capping layer is reduced, and the depth of the bit line cap layer 31 that is etched away may be equivalent to the thickness of the dielectric layer 21.

Optionally, the material of the isolation layer 32, the material of the bit line cap layer 31, and the dielectric layer 21 are the same. For example, the materials of the isolation layer 32, the bit line capping layer 31 and the dielectric layer 21 may all be nitride materials for example, silicon nitride).

In addition, another embodiment also provides a semiconductor memory device. The structure of the semiconductor memory device provided by this specific embodiment can be seen in FIG. 2N, and the semiconductor memory device may be formed by the method shown in FIGS. 1 and 2A-2N. As shown in FIGS. 1 and 2A-2N, the semiconductor memory device provided by this embodiment includes;

A substrate 20 has a bit line contact area 201;

The dielectric layer 21 is located on the surface of the substrate 20, and the dielectric layer 21 has a trench 27 that penetrates the dielectric layer 21 and exposes the bit line contact area 201:

The diffusion barrier layer 29 covers at least part of the sidewalls of the trench

The bit line 30 is filled in the trench 27 and at least the sidewall of the bit line 30 is surrounded by the diffusion barrier layer 29, the bit line 30 is electrically connected to the bit line contact area 201, and the top surface of the bit line 30 is located below the top surface of the dielectric layer 21; and

The bit line capping layer 31 is filled in the trench 27 and located on the top surface of the bit line 30.

Optionally, the trench 27 extends into the substrate 20.

The semiconductor memory device further includes:

The bit line contact layer filled in the trench and is located on the top surface of the bit line contact area 201;

The diffusion barrier layer 29 is also located between the bit line contact layer 28 and the bit line 30, and the bit line 30 is electrically connected to the bit line contact area 201 through the bit line contact layer 28.

Optionally, the material of the bit line 30 is a metal material, and the material of the bit line contact layer 28 is a polysilicon material.

Optionally, the bit cap layer 31 extends out of the dielectric layer 21.

The semiconductor memory device further includes:

The isolation layer 32 is disposed on the sidewall surface of the dielectric layer 21 extending from the bit line cap layer 31.

Optionally, the material of the isolation layer 32, the material of the bit line cap layer 31, and the material of the dielectric layer 21 are all the same.

The method for forming the semiconductor memory device provided in this embodiment includes forming a trench penetrating the dielectric layer to make at bit line profile, and then filling the trench with a first conductive material to form a bit line, in comparison with the existing methods of forming a bit line by depositing a conductive film layer followed by subsequent patterning, of the conductive film layer into the bit line. First, since the bit line is formed by trench tilling, there is no bending defects due to the small line width of each bit line. In addition, since there is no need to perform wet cleaning on the bit line metal or polysilicon, problems such as bit line sidewall erosion and sidewall oxidation are avoided and electron conductivity is improved, thereby reducing the internal resistance of the semiconductor memory device.

The exemplary embodiments of the present disclosure are specifically shown and described above, it should be understood that the present disclosure is not limited to the detailed structure, arrangement or implementation method described herein. The above are only the preferred embodiments of this application. It should be pointed out that for those of ordinary skill in the art, without departing from the principle of this application, several improvements and modifications can be made, and these improvements and modifications should also be considered as the protection scope of this application.

The present disclosure intends to cover various modifications and equivalent arrangements included in the spirit and scope of the appended claims.

What is claimed is:

1. A method for forming a semiconductor memory device comprising:
providing a substrate having a bit fine contact area, wherein a dielectric layer disposed on a top surface of the substrate;
forming a trench penetrating the dielectric layer and exposing the bit line contact are
filling a first conductive material in the trench to form a bit line, wherein a top surface of the bit line is configured to be lower than a top surface of the dielectric layer; and
filling in the trench with an insulating material to form a bit line capping layer on the top surface of the bit line.

2. The method for forming the semiconductor memory device according to claim 1, wherein a step forming the trench penetrating the dielectric layer and exposing the bit line contact region comprises:
forming a liner layer on a surface of the dielectric layer;
forming a first mask layer on a surface of the liner layer, wherein the first mask layer has an opening exposing the liner layer;
forming a second mask layer filling the opening;
etching back the first mask layer;
forming an etching window in the second mask layer exposing the liner layer; and
etching the liner layer and the dielectric layer along the etching window to form a trench, wherein the trench penetrates the dielectric layer and the liner layer and exposes the bit line contact area.

3. The method for forming the semiconductor memory device according o claim 2, wherein a step of forming the first mask layer on the surface of the liner layer comprises:
forming a photoresist layer on the surface of the liner layer, wherein the photoresist layer comprises an initial opening exposing the liner layer, wherein the first mask layer is disposed on a sidewall of the initial opening; and
removing the photoresist layer and an opening exposing the liner layer is formed in the first mask layer.

4. The method for forming the semiconductor memory device a cording to claim 2, wherein a material of the substrate layer is an oxide, a material of the dielectric layer is silicon nitride, and a material of the first mask layer is an amorphous silicon, and a material of the second mask layer is an organic mask material.

5. The method for fanning the semiconductor memory device according to claim 2, wherein the method further comprises a step before forming the bit line:
filling a second conductive material in the trench to form a bit line contact layer on a top surface of the bit line contact area.

6. The method for tanning a semiconductor memory device according to claim 5, wherein the trench extends into the substrate, the bit line contact layer protrudes above of the top surface of the substrate, and a top surface of the bit line contact layer is below the top surface of the dielectric layer.

7. The method for forming the semiconductor memory device according to claim 5, wherein there forming the bat line includes:
forming a diffusion barrier layer on a sidewall of the trench and the top surface of the bit line contact layer, wherein the first conductive material in the trench covers a surface of the diffusion barrier layer.

8. The method for forming the semiconductor memory device according to claim 7, wherein the first conductive material is a metal material, and wherein the second conductive material is a polysilicon material.

9. The method for forming the semiconductor memory device according to claim 1, wherein the bit line capping layer extends out of the dielectric layer; wherein after forming the bit line capping layer on the top surface of the bit line, the method further comprises steps of:
forming an isolation layer on sidewalls of the bit line cap layer, and
etching the dielectric layer using the isolation layer as a third mask to expose the top surface of the substrate, wherein the dielectric layer remaining on a side surface of the bit line serves as a sidewall protection layer for the bit line.

10. The method for thrilling the semiconductor memory device according to claim 9, wherein a material of the isolation layer, a material of the bit line capping layer, and a material of the dielectric layer are a same.

11. A semiconductor memory device, comprising:
a substrate including a bit line contact area;
a dielectric layer disposed on a top surface of the substrate, wherein the dielectric layer comprises a trench penetrating the dielectric layer and exposing the bit line contact area;
a diffusion barrier layer disposed at least on a sidewall of the trench;
a bit line filled in the trench, wherein sidewalls of the bit line are surrounded by the diffusion barrier layer, wherein the bit line is electrically connected to the bit line contact area, and wherein a top surface of the bit line is configured to be lower than a top surface of the dielectric layer; and
a bit line capping layer disposed on the top surface of the bit line and filling the trench.

12. The semiconductor memory device of claim 11, wherein the trench extends into the substrate, wherein the semiconductor memory device further comprises:
a bit line contact layer filled in the trench, wherein the bit line contact layer is disposed on a top surface of the bit line contact area;
wherein the diffusion barrier layer is disposed between the bit line contact layer and the bit line, and wherein the bit line is electrically connected to the bit line contact area through the bit line contact layer.

13. The semiconductor memory device according to claim 12, wherein a material of the bit line is a metal material, and wherein a material of the bit line contact layer is a polysilicon material.

14. The semiconductor memory device of claim 11, wherein:
the bit line capping layer extends out of the dielectric layer; and
the semiconductor memory device further comprises an isolation layer disposed on a sidewall surface of the dielectric layer which extends from the bit line cap layer.

15. The semiconductor memory device according to claim 14, wherein a material of the isolation layer, a material of the bit line capping layer, and a material of the dielectric layer are a same.
